(19) United States
(12) Patent Application Publication
(10) Pub. No.: US 2023/0197886 A1
(43) Pub. Date: Jun. 22, 2023

(54) SEMICONDUCTOR APPARATUS

(71) Applicant: ROHM Co., LTD., Kyoto (JP)

(72) Inventor: Kazuya Masuyama, Kyoto (JP)

(21) Appl. No.: 18/065,979

(22) Filed: Dec. 14, 2022

(30) Foreign Application Priority Data
Dec. 21, 2021 (JP) 2021-206799

(51) Int. Cl. H01L 33/02; H01L 33/38; H01L 23/00

(52) U.S. Cl. CPC H01L 33/02; H01L 33/382; H01L 24/26; H01L 33/62

(57) ABSTRACT

Provided is a semiconductor apparatus including a substrate, a semiconductor chip, a connection material, a bonding wire, and a partition, in which the semiconductor chip is arranged on the substrate through the connection material, the bonding wire includes a first end and a second end and is connected to the semiconductor chip at the first end and connected to the substrate at the second end, and the partition is arranged on the substrate, at a position between the semiconductor chip and the second end in plan view.

### CROSS REFERENCE TO RELATED APPLICATIONS

This application claims priority benefit of Japanese Patent Application No. JP 2021-206799 filed in the Japan Patent Office on Dec. 21, 2021. Each of the above-referenced applications is hereby incorporated herein by reference in its entirety.

### BACKGROUND

The present disclosure relates to a semiconductor apparatus.

A semiconductor light emitting apparatus is described in, for example, Japanese Patent Laid-open No. 2020-167366. The semiconductor light emitting apparatus described in Japanese Patent Laid-open No. 2020-167366 includes a substrate, a semiconductor light emitting element, and a wire. The substrate includes a base and a conductive portion. The conductive portion is arranged on a main surface of the base. The semiconductor light emitting element is arranged on the conductive portion. The wire includes a first end and a second end. The wire is connected to the semiconductor light emitting element at the first end and connected to the conductive portion at the second end.

### SUMMARY

The semiconductor light emitting element is connected to the conductive portion through, for example, a die bonding paste applied to a portion between the semiconductor light emitting element and the conductive portion. The die bonding paste may ooze out in connecting the semiconductor light emitting element and the conductive portion. If the die bonding paste oozes out to the part of the conductive portion connected to the second end of the wire, the connection between the second end of the wire and the conductive portion may become poor.

The present disclosure has been made in view of the problem of the technique in the related art. More specifically, it is desirable to provide a semiconductor apparatus that can suppress poor connection between a bonding wire and a substrate.

A semiconductor apparatus according to an embodiment of the present disclosure includes a substrate, a semiconductor chip, a connection material, a bonding wire, and a partition. The semiconductor chip is arranged on the substrate through the connection material. The bonding wire includes a first end and a second end. The bonding wire is connected to the semiconductor chip at the first end and connected to the substrate at the second end. The partition is arranged on the substrate, at a position between the semiconductor chip and the second end in plan view.

According to the semiconductor apparatus of an embodiment of the present disclosure, poor connection between the bonding wire and the substrate can be suppressed.

### BRIEF DESCRIPTION OF THE DRAWINGS

FIG. 1 is a plan view of a semiconductor apparatus 100;

FIG. 2 is a cross-sectional view taken along II-II in

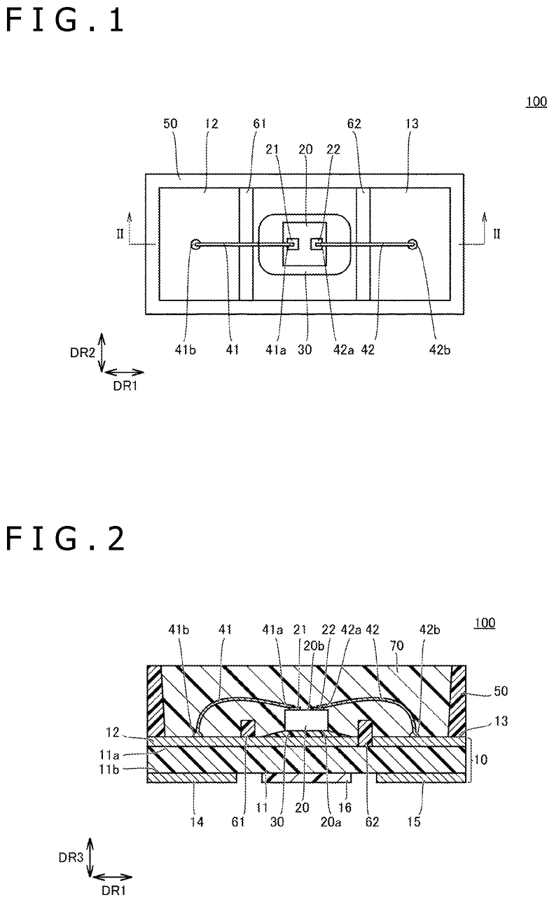

FIG. 1;

FIG. 3 is a process chart illustrating a manufacturing method of the semiconductor apparatus 100;

FIG. 4 is a cross-sectional view describing a preparation step S1;

FIG. 5 is a cross-sectional view describing a reflector formation step S2;

FIG. 6 is a cross-sectional view describing a die bonding step S3;

FIG. 7 is a cross-sectional view describing a wire bonding step S4;

FIG. 8 is a cross-sectional view describing a resin sealing step S5;

FIG. 9 is a cross-sectional view of a semiconductor apparatus 200; and

FIG. 10 is a cross-sectional view of the semiconductor apparatus 100 according to a modification.

### DETAILED DESCRIPTION OF THE PREFERRED EMBODIMENT

Details of an embodiment of the present disclosure will be described with reference to the drawings. In the following drawings, the same reference signs are provided to the same or corresponding parts, and duplicate description will not be repeated.

### Configuration of Semiconductor Apparatus According to Embodiment

A configuration of a semiconductor apparatus according to the embodiment will now be described. The semiconductor apparatus according to the embodiment will be referred to as a semiconductor apparatus 100.

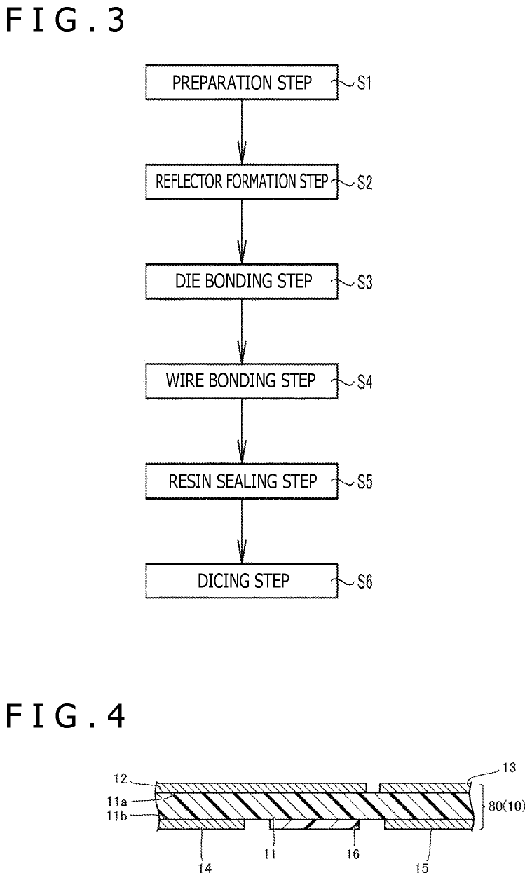

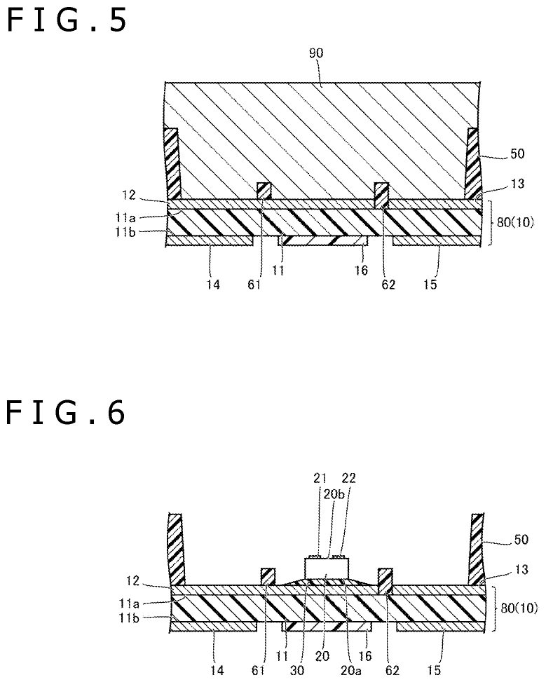

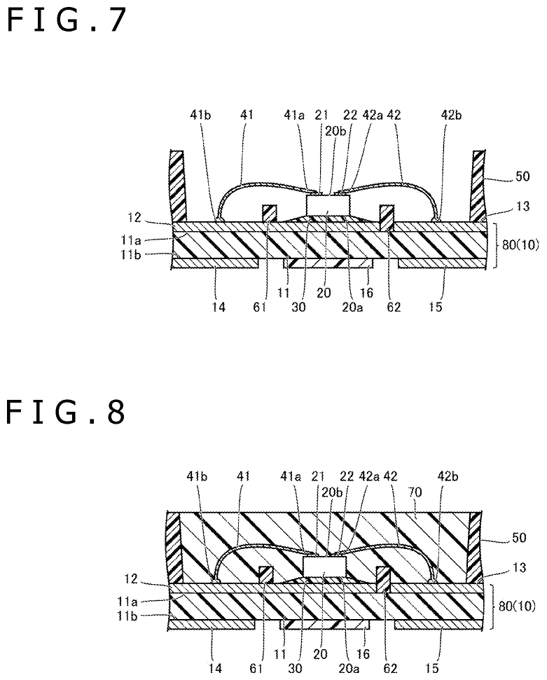

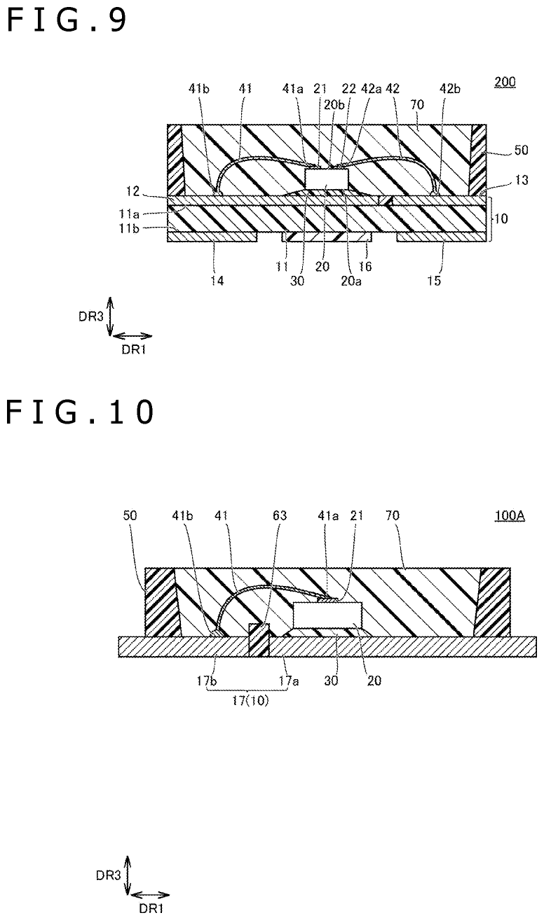

FIG. 1 is a plan view of the semiconductor apparatus 100. Note that a sealing resin 70 is not illustrated in FIG. 1. FIG. 2 is a cross-sectional view taken along II-II in FIG. 1. As illustrated in FIGS. 1 and 2, the semiconductor apparatus 100 includes a substrate 10, a semiconductor chip 20, a connection material 30, a bonding wire 41, a bonding wire 42, a reflector 50, a partition 61, a partition 62, and the sealing resin 70.

The substrate 10 includes, for example, a base 11, a conductor pattern 12, a conductor pattern 13, a conductor pattern 14, a conductor pattern 15, and a resist 16. A longitudinal direction of the substrate 10 will be referred to as a first direction DR1. A direction orthogonal to the first direction DR1 in plan view will be referred to as a second direction DR2. A direction orthogonal to the first direction DR1 and the second direction DR2 will be referred to as a third direction DR3.

The base 11 is, for example, rectangular in plan view. The base 11 contains an electrically insulating material. The base 11 contains, for example, glass epoxy. The base 11 includes a first main surface 11a and a second main surface 11b. The first main surface 11a and the second main surface 11b are end surfaces of the base 11 in the third direction DR3. The second main surface 11b is an opposite surface of the first main surface 11a.

The conductor pattern 12 and the conductor pattern 13 are arranged on the first main surface 11a. The conductor pattern 12 and the conductor pattern 13 are, for example, rectangular in plan view. The conductor pattern 12 and the conductor pattern 13 are spaced apart and lined up along the first direction DR1. The conductor pattern 12 and the conductor pattern 13 include conductors. The conductor pattern 12 and the conductor pattern 13 contain, for example, copper (Cu).

The conductor pattern 14 and the conductor pattern 15 are arranged on the second main surface 11b. The conductor pattern 14 and the conductor pattern 15 are, for example, rectangular in plan view. The conductor pattern 14 and the conductor pattern 15 are spaced apart and lined up along the first direction DR1. The conductor pattern 14 and the conductor pattern 15 include conductors. The conductor pattern 14 and the conductor pattern 15 contain, for example, Cu. The conductor pattern 14 and the conductor pattern 15 are arranged on, for example, end portions of the second main surface 11b in the first direction DR1.

Although not illustrated, a first through hole and a second through hole are formed in the base 11. The first through hole is arranged to overlap with the conductor pattern 12 and the conductor pattern 14 in plan view. The second through hole is arranged to overlap with the conductor pattern 13 and the conductor pattern 15 in plan view. A conductor (not illustrated) embedded in the first through hole electrically connects the conductor pattern 12 and the conductor pattern 14. A conductor (not illustrated) embedded in the second through hole electrically connects the conductor pattern 13 and the conductor pattern 15.

The resist 16 is arranged on the second main surface 11b. The resist 16 is arranged between the conductor pattern 14 and the conductor pattern 15 in the first direction DR1. The resist 16 includes, for example, a solder resist.

The semiconductor chip 20 is, for example, a light emitting element. The semiconductor chip 20 is, for example, a light emitting diode (LED). The semiconductor chip 20 includes a bottom surface 20a and an upper surface 20b. The semiconductor chip 20 is arranged on the substrate 10. Specifically, the semiconductor chip 20 is arranged on the conductor pattern 12. The bottom surface 20a and the upper surface 20b are end surfaces of the semiconductor chip 20 in the third direction DR3. The bottom surface 20a faces the substrate 10 (conductor pattern 12). The upper surface 20b is an opposite surface of the bottom surface 20a. A bonding pad 21 and a bonding pad 22 are formed on the upper surface 20b.

The connection material 30 is arranged between the semiconductor chip 20 (bottom surface 20a) and the substrate 10 (conductor pattern 12). Accordingly, the semiconductor chip 20 is connected to the substrate 10. The connection material 30 contains, for example, a die bonding paste. The die bonding paste contains a resin material. The die bonding paste is, for example, non-conductive.

The bonding wire 41 includes a first end 41a and a second end 41b. The second end 41b is an end on the opposite side of the first end 41a. The bonding wire 41 is connected to the bonding pad 21 at the first end 41a. The bonding wire 41 is connected to the conductor pattern 12 at the second end 41b. The bonding wire 41 contains, for example, gold (Au).

The bonding wire 42 includes a first end 42a and a second end 42b. The second end 42b is an end on the opposite side of the first end 42a. The bonding wire 42 is connected to the bonding pad 22 at the first end 42a. The bonding wire 42 is connected to the conductor pattern 13 at the second end 42b. The bonding wire 42 contains, for example, gold.

The reflector 50 is arranged on the substrate 10. The reflector 50 is arranged, for example, to surround the conductor pattern 12 and the conductor pattern 13 in plan view. More specifically, the reflector 50 is arranged along an outer periphery of the first main surface 11a in plan view. The reflector 50 rises from the substrate 10 along the third direction DR3. The reflector 50 contains a material that reflects light generated by the semiconductor chip 20. The reflector 50 contains, for example, a resin material mixed with titanium oxide (TiO₂). An inner surface of the reflector 50 may be inclined such that the distance between the inner surface and an outer surface of the reflector 50 becomes larger toward a lower end of the reflector 50. Note that the light from the semiconductor chip 20 reflected by the reflector 50 is emitted from the upper side of the semiconductor apparatus 100.

The partition 61 and the partition 62 are arranged on the substrate 10. More specifically, the partition 61 is arranged on the conductor pattern 12, and the partition 62 is arranged on a part of the first main surface 11a between the conductor pattern 12 and the conductor pattern 13. The partition 61 and the partition 62 extend along the second direction DR2 in plan view. An upper end of the partition 61 and an upper end of the partition 62 protrude more than the surface of the conductor pattern 12 (conductor pattern 13). However, the upper end of the partition 61 and the upper end of the partition 62 are preferably closer to the substrate 10 than the upper surface 20b. The partition 61 and the partition 62 contain, for example, a resin material. Preferably, the partition 61 and the partition 62 contain the same material as the reflector 50.

The sealing resin 70 is arranged in a space defined by the reflector 50 and the substrate 10 in such a manner as to cover the semiconductor chip 20, the connection material 30, the bonding wire 41, the bonding wire 42, the partition 61, and the partition 62. The sealing resin 70 contains, for example, a transparent resin.

### Manufacturing Method of Semiconductor Apparatus According to Embodiment

A manufacturing method of the semiconductor apparatus 100 will be described below.

FIG. 3 is a process chart illustrating the manufacturing method of the semiconductor apparatus 100. As illustrated in FIG. 3, the manufacturing method of the semiconductor apparatus 100 includes a preparation step S1, a reflector formation step S2, a die bonding step S3, a wire bonding step S4, a resin sealing step S5, and a dicing step S6.

FIG. 4 is a cross-sectional view describing the preparation step S1. As illustrated in FIG. 4, a substrate 80 is prepared in the preparation step S1. The substrate 80 includes a plurality of substrates 10.

FIG. 5 is a cross-sectional view describing the reflector formation step S2. As illustrated in FIG. 5, the reflector 50 is formed in the reflector formation step S2. The partition 61 and the partition 62 are also formed in the reflector formation step S2. The reflector 50, the partition 61, and the partition 62 are formed by transfer molding with, for example, a mold 90. The part of the mold 90 where the reflector 50, the partition 61, and the partition 62 are to be formed is a flow path of the resin material of the reflector 50, the partition 61, and the partition 62. Therefore, the resin material of the reflector 50, the partition 61, and the partition 62 is injected to a portion between the mold 90 and the substrate 80, and the resin material is cured to form the reflector 50, the partition 61, and the partition 62.

FIG. 6 is a cross-sectional view describing the die bonding step S3. As illustrated in FIG. 6, the connection material 30 is used to connect the semiconductor chip 20 to the conductor pattern 12 in the die bonding step S3. In the die bonding step S3, first, an uncured connection material 30 is applied over the conductor pattern 12. Second, the semiconductor chip 20 is mounted on the uncured connection material 30. Third, the connection material 30 is heated and cured to connect the semiconductor chip 20 to the conductor pattern 12 through the connection material 30.

FIG. 7 is a cross-sectional view describing the wire bonding step S4. In the wire bonding step S4, wire bonding is performed to connect the bonding pad 21 and the conductor pattern 12 through the bonding wire 41 and to connect the bonding pad 22 and the conductor pattern 13 through the bonding wire 42 as illustrated in FIG. 7.

FIG. 8 is a cross-sectional view describing the resin sealing step S5. In the resin sealing step S5, a dispenser is used to pot an uncured sealing resin 70 into the space defined by the substrate 10 and the reflector 50, and the uncured sealing resin 70 is heated and cured. In the dicing step S6, the substrate 80 is cut to be diced into a plurality of semiconductor apparatuses 100. The semiconductor apparatus 100 with the structure illustrated in FIGS. 1 and 2 is formed in this way.

### Advantageous Effect of Semiconductor Apparatus According to Embodiment

An advantageous effect of the semiconductor apparatus 100 will be described by comparing the semiconductor apparatus 100 with a semiconductor apparatus according to a comparison example. The semiconductor apparatus according to the comparison example will be referred to as a semiconductor apparatus 200.

FIG. 9 is a cross-sectional view of the semiconductor apparatus 200. As illustrated in FIG. 9, the semiconductor apparatus 200 includes the substrate 10, the semiconductor chip 20, the connection material 30, the bonding wire 41, the bonding wire 42, the reflector 50, and the sealing resin 70. In this regard, the semiconductor apparatus 200 and the semiconductor apparatus 100 have a common configuration. The semiconductor apparatus 200 does not include the partition 61 and the partition 62. In this regard, the semiconductor apparatus 200 and the semiconductor apparatus 100 have different configurations.

In the semiconductor apparatus 200, the connection material 30 may ooze out in connecting the semiconductor chip 20 to the conductor pattern 12 through the connection material 30. Although the connection material 30 is also spread over the conductor pattern 13 in some cases, the connection material 30 tends to be spread particularly over the conductor pattern 12. The spread of the connection material 30 to the part of the conductor pattern 12 connected to the bonding wire 41 through the second end 41b or to the part of the conductor pattern 13 connected to the bonding wire 42 through the second end 42b may cause poor connection between the bonding wire 41 and the conductor pattern 12 or poor connection between the bonding wire 42 and the conductor pattern 13.

In the semiconductor apparatus 100, the connection material 30 may also ooze out in connecting the semiconductor chip 20 to the conductor pattern 12 through the connection material 30. However, the partition 61 is arranged between the second end 41b and the semiconductor chip 20, and the partition 62 is arranged between the second end 42b and the semiconductor chip 20 in the semiconductor apparatus 100. Accordingly, the oozing of the connection material 30 is stopped by the partition 61 and the partition 62, and this suppresses the spread of the connection material 30 to the part of the conductor pattern 12 connected to the bonding wire 41 through the second end 41b and the part of the conductor pattern 13 connected to the bonding wire 42 through the second end 42b. Therefore, the semiconductor apparatus 100 can suppress the poor connection between the bonding wire 41 and the conductor pattern 12 and the poor connection between the bonding wire 42 and the conductor pattern 13.

The partition 61, the partition 62, and the reflector 50 can be formed at the same time when the partition 61 and the partition 62 contain the same material as the reflector 50. This can suppress the poor connection between the bonding wire 41 and the conductor pattern 12 and the poor connection between the bonding wire 42 and the conductor pattern 13 while suppressing the increase in the manufacturing cost of the semiconductor apparatus 100.

When the substrate 10 does not include the resist 16, the substrate 10 may be distorted as the mold 90 is brought into contact with the substrate 10. A gap is generated between the mold 90 and the substrate 10 when the substrate 10 is distorted, and the resin material of the reflector 50, the partition 61, and the partition 62 may also flow into the gap. On the other hand, when the substrate 10 includes the resist 16, the substrate 10 is supported at three points by the conductor pattern 14, the conductor pattern 15, and the resist 16 as the mold 90 and the substrate 10 come into contact with each other, and the substrate 10 is unlikely to be distorted.

If the positions of the upper end of the partition 61 and the upper end of the partition 62 in the third direction DR3 are too high, the partition 61 and the partition 62 may become an obstacle in applying the sealing resin 70 into the space defined by the substrate 10 and the reflector 50. Arranging the upper end of the partition 61 and the upper end of the partition 62 closer to the substrate 10 than the upper surface 20b can prevent the partition 61 and the partition 62 from becoming an obstacle in applying the sealing resin 70.

### (Modification)

A modification of the semiconductor apparatus 100 will be described below.

FIG. 10 is a cross-sectional view of the semiconductor apparatus 100 according to the modification. As illustrated in FIG. 10, the substrate 10 may be a lead frame 17. The lead frame 17 includes a first part 17a and a second part 17b. The semiconductor chip 20 is arranged on the first part 17a through the connection material 30. The bonding wire 41 is connected to the bonding pad 21 at the first end 41a and connected to the second part 17b at the second end 41b. The partition 63 is arranged between the semiconductor chip 20 and the second end 41b in plan view. The partition 63 preferably contains the same material as the reflector 50. In this case, the partition 63 also suppresses the oozing of the connection material 30, and this can suppress the poor connection between the bonding wire 41 and the substrate 10 (lead frame 17).

While the embodiment of the present disclosure has been described, the embodiment can also be modified in various ways. The scope of the present technology is not limited to the embodiment. The scope of the present technology is indicated by the claims, and all changes within the meaning and range of equivalents of the claims are intended to be included in the scope of the present technology.

What is claimed is:

1. A semiconductor apparatus comprising:
a substrate;
a semiconductor chip;
a connection material;
a bonding wire; and
a partition, wherein
the semiconductor chip is arranged on the substrate through the connection material,
the bonding wire includes a first end and a second end and is connected to the semiconductor chip at the first end and connected to the substrate at the second end, and
the partition is arranged on the substrate, at a position between the semiconductor chip and the second end in plan view.

2. The semiconductor apparatus according to claim 1, further comprising:
a reflector arranged on the substrate, wherein
the semiconductor chip is a light emitting element, and
the partition contains a same material as the reflector.

3. The semiconductor apparatus according to claim 2, wherein
the substrate includes a base including a first main surface and a second main surface and a first conductor pattern and a second conductor pattern that are arranged on the first main surface, and
the first conductor pattern and the second conductor pattern are spaced apart and lined up along a longitudinal direction of the substrate in plan view.

4. The semiconductor apparatus according to claim 3, wherein
the semiconductor chip is arranged on the first conductor pattern through the connection material, and
the bonding wire is connected to the first conductor pattern at the second end.

5. The semiconductor apparatus according to claim 3, wherein
the substrate further includes a third conductor pattern and a fourth conductor pattern that are arranged on the second main surface and a resist arranged on the second main surface, and
the resist is arranged between the third conductor pattern and the fourth conductor pattern in the longitudinal direction.

6. The semiconductor apparatus according to claim 2, wherein
an upper end of the partition is closer to the substrate than an upper surface of the semiconductor chip.

7. The semiconductor apparatus according to claim 1, wherein
the connection material is a die bonding paste containing a resin material.
